(19) United States
(12) Patent Application Publication
(10) Pub. No.: US 2011/0051351 A1
(43) Pub. Date: Mar. 3, 2011

(54) Circuit board, semiconductor device including the same, memory module, memory system, and manufacturing method of circuit board

(75) Inventor: Shiro Harashima, Tokyo (JP)

(73) Assignee: Elpida Memory, Inc., Tokyo (JP)

(21) Appl. No.: 12/805,264

(22) Filed: Jul. 21, 2010

(30) Foreign Application Priority Data
Aug. 25, 2009 (JP) 2009-194143

(51) Int. Cl. G06F 1/16; H01R 12/30; H05K 7/02

(52) U.S. Cl. 361/679.31; 174/261; 361/783

(57) ABSTRACT

A circuit board according to the present invention includes a main surface, a back surface parallel to the main surface, a side surface positioned between edges of the main surface and the back surface, and first and second board terminals covering a portion of the main surface and a portion of the side surface, respectively. According to the present invention, because the board terminals are provided not only on the main surface but also on the side surface of the circuit board, the total number of board terminals can be increased while maintaining sufficient pitch and width of the board terminals.

### BACKGROUND OF THE INVENTION

1. Field of the Invention

The present invention relates to a circuit board and a semiconductor device including the circuit board, and more particularly relates to a circuit board in which it is possible to reduce the number of board terminals to be formed on a main surface, and a semiconductor device including the circuit board. The present invention also relates to a memory module and a memory system including the circuit board and a manufacturing method of the circuit board.

2. Description of Related Art

DRAM (Dynamic Random Access Memory) is widely used as a main memory in personal computers and servers. In a personal computer or a server, instead of mounting a DRAM directly on a motherboard, it is a common to attach the DRAM to a socket (a memory slot) provided on the motherboard in the form of a memory module mounted onto a module board (see Japanese Patent Application Laid-open No. 2006-324326).

In recent years, the amount of input/output data or number of addresses in DRAMs have continued to increase. Therefore, there has been a concern that the number of terminals to be provided on a memory module may reach a number that cannot be accommodated within the area that has been set by the standards. The number of the board terminals on a memory module can be increased by decreasing a pitch and a width of the board terminals. However, the contact reliability of the memory module with the socket disadvantageously decreases when the pitch and the width of the board terminals is decreased. Particularly, in recent years, there has been a strong demand for lowering power consumption and increasing operation speed. To achieve this, it is necessary to avoid an increase in the electric resistance that arises due to downsizing of the board terminals.

The above problem is not limited to memory modules, and the same problem arises in circuit boards having board terminals and semiconductor devices including the circuit board.

### SUMMARY

In one embodiment, there is provided a circuit board that includes: a main surface; a back surface parallel to the main surface; a side surface positioned between edges of the main surface and the back surface; and first and second board terminals covering a portion of the main surface and a portion of the side surface, respectively.

In another embodiment, there is provided a semiconductor device that includes: a circuit board including a main surface, a back surface parallel to the main surface, a side surface positioned between edges of the main surface and the back surface, and first and second board terminals covering a portion of the main surface and a portion of the side surface, respectively; and a semiconductor chip mounted on the main surface of the circuit board and having a plurality of chip terminals, wherein the first and second board terminals of the circuit board are electrically connected to corresponding ones of the chip terminals of the semiconductor chip via an internal wiring provided inside the circuit board.

In still another embodiment, there is provided a manufacturing method of a circuit board that includes: forming a hole that communicates from a main surface to a back surface of a board; forming a metal film on a surface of the board including an internal wall of the hole; forming a first board terminal on the main surface and forming a second board terminal on the internal wall of the hole by patterning the metal film; and cutting the board along the hole.

According to the present invention, because board terminals are provided not only on the main surface but also on a side surface of the circuit board, the total number of the board terminals can be increased while maintaining sufficient pitch and width of the board terminals. Furthermore, the board terminals that are provided on the side surface are formed by not only exposing the internal wiring, but by covering the side surface of the circuit board with the board terminals. As a result, in contrast to the semiconductor device described in Japanese Patent Application Laid-open No. 2006-324326, reliable electric connection can be achieved.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic plan view of a configuration of a memory module according to a first embodiment of the present invention;

FIG. 2 is an enlarged view of a region 108 shown in FIG. 1;

FIG. 3 is a cross-sectional view taken along a line A-A′ shown in FIG. 2;

FIG. 4 is a schematic plan view showing a state where the memory module according to the first embodiment is attached to a socket;

FIG. 5 is a schematic partial cross-sectional view showing a state where the memory module according to the first embodiment is attached to a socket;

FIGS. 6A to 6F are process diagrams for explaining the manufacturing method of the memory module according to the first embodiment;

FIGS. 7A and 7B are diagrams for explaining the manufacturing method of the memory module according to a modification example of the first embodiment;

FIG. 8 is a schematic plan view of a configuration of a memory module according to the second embodiment of the present invention;

FIGS. 9A and 9B are diagrams showing a configuration of a memory module according to a third embodiment of the present invention, where FIG. 9A is a schematic perspective view of the memory module and FIG. 9B is a cross-sectional view of the memory module taken along a line B-B′ shown in FIG. 9A; and

FIG. 10 is a modification example of the third embodiment.

### DETAILED DESCRIPTION OF THE EMBODIMENTS

Preferred embodiments of the present invention will be explained below in detail with reference to the accompanying drawings.

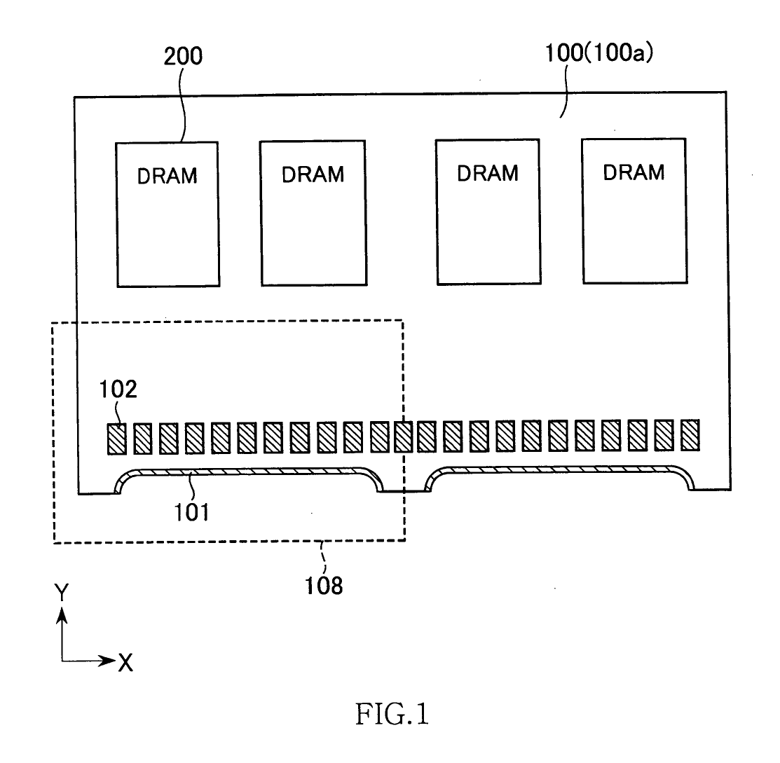

FIG. 1 is a schematic plan view of a configuration of a memory module according to a first embodiment of the present invention.

The memory module according to the first embodiment is a so-called SO-DIMM, and more specifically it is a semiconductor device in which a plurality (four in this example) of DRAMs 200 are mounted on a main surface 100a of a module board (a circuit board) 100. It is needless to say that the target of the present invention is not limited to SO-DIMMs, and the present invention can be also applied to various types of DIMMs (including Unbuffered-DIMM or FB-DIMM). Moreover, the semiconductor chip to be mounted is not limited to the DRAM, but can be other semiconductor memories (such as a SRAM, a flash memory, and a PRAM). Furthermore, the semiconductor chip to be mounted on the circuit board does not need to be a memory, but can be a device such as a CPU or a microcomputer.

The main surface 100a of the module board 100 is substantially rectangular with a long side extending in an X direction and a short side extending in a Y direction. The DRAMs 200 are arrayed in the X direction in an upper part of the main surface 100a and board terminals (first board terminals) 102 are arrayed in the X direction in a lower part of the main surface 100a. Although not shown in FIG. 1, a back surface of the module board 100 that is parallel to the main surface 100a has the same configuration as the main surface 100a.

The board terminals 102 provided on the main surface and the back surface of the module board 100 are mainly used as signal terminals. The signal terminal can be an address terminal to which an address signal is input, a command terminal to which a command signal is input, a clock terminal to which a clock signal is input, or a data terminal to which data is input or from which data is output.

As shown in FIG. 1, in the first embodiment, a part of the lower side of the module board 100 is cut out and board terminals (second board terminals) 101 are provided on a side surface of the cutout part. The board terminals 101 are not only provided on the side surface of the module board 100 but a portion of the board terminals 101 is turned toward the main surface and the back surface. In the first embodiment, the board terminals 101 are provided at two places. One of the board terminals 101 is used as a power terminal to which a power potential (VDD) is supplied and the other board terminal 101 is used as a power terminal to which a ground potential (GND) is supplied. As a result, power terminals to which the power potential (VDD) or the ground potential (GND) is supplied are not included in the board terminals 102 that are provided on the main surface or the back surface. Accordingly, it is supposed that a larger number of signal terminals can be arranged on the main surface and the back surface. This does not mean that not a single power terminal is included in the board terminals 102; some of the board terminals 102 are used as terminals to which a reference power is supplied. Moreover, it also does not mean that no power terminal to which the power potential (VDD) or the ground potential (GND) is supplied is included in the board terminals 102; these potentials can be supplied to some of the board terminals 102.

As shown in FIG. 1, the terminal width of the board terminals 101 in the X direction is significantly wider than the terminal width of the board terminals 102. As a result, the electric resistance of the power terminal is advantageously reduced as compared to that in a conventional technology.

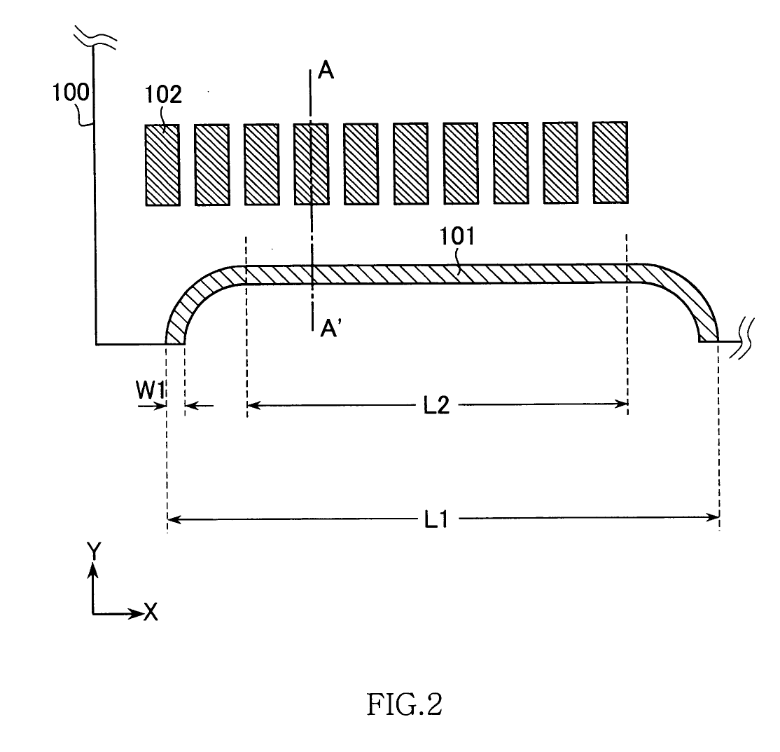

FIG. 2 is an enlarged view of a region 108 shown in FIG. 1.

As shown in FIG. 2, an overall width of the board terminal 101 in the X direction is L1 and an overall width of a flat portion provided inside the cut out portion in the X direction is L2. The value of the width L1 can vary depending on the length of the module board 100 in the X direction or the number of board terminals 101. For example, in the case of an SO-DIMM having a width of 65 mm, the board terminals 101 having the width L1 of 30 mm can be provided at as many as two places. Although the board terminals 101 are provided at two places in the first embodiment, the board terminals 101 can be provided at four or eight places when there is a need to provide more board terminals when there are a number of different types of power sources or upon considering the arrangement balance of the power sources. This feature is explained in detail later as a second embodiment of the present invention.

The width L2 also corresponds to a width of a flat portion at which a socket (a conductor) makes a contact. Note that a configuration is allowable in which the socket achieves conductance by engaging even with portions (curved portions on both sides of the width L1) other than the flat portion and such a configuration is not excluded from the scope of the present invention. A width W1 is a width of the portion of the board terminals 101 that is formed so as to be turned toward the main surface and the back surface of the module board 100. The reason for providing such a wrapping portion is that there is a need to secure a margin so that the terminals on the side surface are not etched away during the etching process for forming terminals.

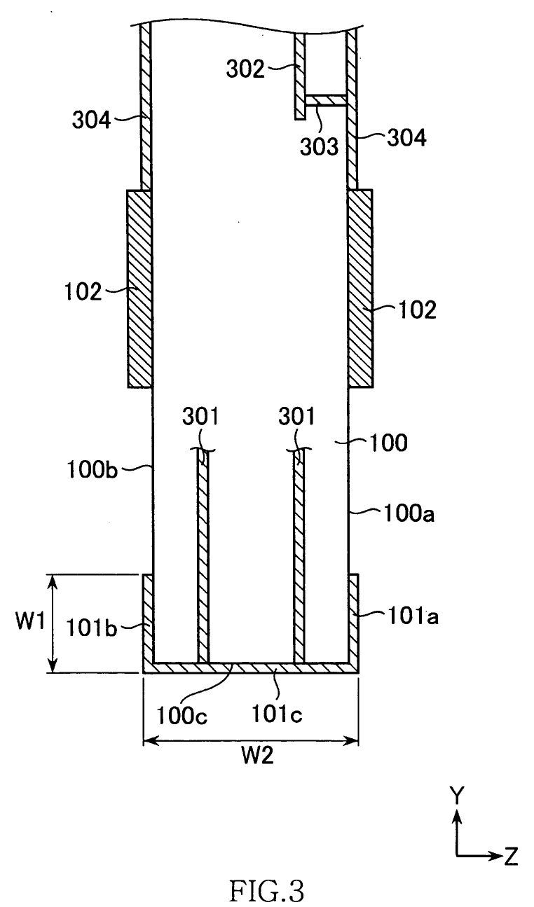

FIG. 3 is a cross-sectional view taken along a line A-A′ shown in FIG. 2.

As shown in FIG. 3, the board terminal 101 includes a first part 101c formed on a side surface 100c over a total width W2 between the edges of the main surface 100a and a back surface 100b, a second part 101a formed on the main surface 100a, and a third part 101b formed on the back surface 100b. The first part 101c and the second part 101a are mutually connected via the edge of the main surface 100a. Similarly, the first part 101c and the third part 101b are mutually connected via the edge of the back surface 100b.

The side surface 100c of the module board 100 is, as shown in FIG. 3, a surface located between the edges of the main surface 100a and the back surface 100b, and the total width W2 between the edges corresponds to a length in a Z direction. The main surface 100a and the back surface 100b of the module board 100 are mutually parallel surfaces and the width W1 corresponds to a length in the Y direction in FIG. 3.

The board terminals 101 having such a configuration are connected to a plurality of power wirings 301 provided within the module board 100. Thus, an important feature of the first embodiment is not that the power wirings 301 are exposed on the side surface 100c of the module board 100, but that the board terminals 101 are formed so as to cover the side surface 100c of the module board 100. Consequently, it is possible to achieve higher connection reliability. On the other hand, if only the power wirings 301 are exposed on the side surface 100c of the module board 100, it is difficult to achieve reliable conductance with the socket. Another important feature is that each of the board terminals 101 is connected to a plurality of the power wirings 301. With this configuration, a reliable electrical connection can be achieved between each of the power wirings 301 and the board terminal 101.

The board terminals 102 provided on the main surface 100a and the back surface 100b are connected to signal wirings 304 provided on the main surface 100a and the back surface 100b of the module board 100. The signal wiring 304 is connected via a through hole electrode 303 to the signal wiring 302 provided within the module board 100. The power wiring 301 and the signal wiring 302 are each connected to corresponding terminals of the DRAMs 200.

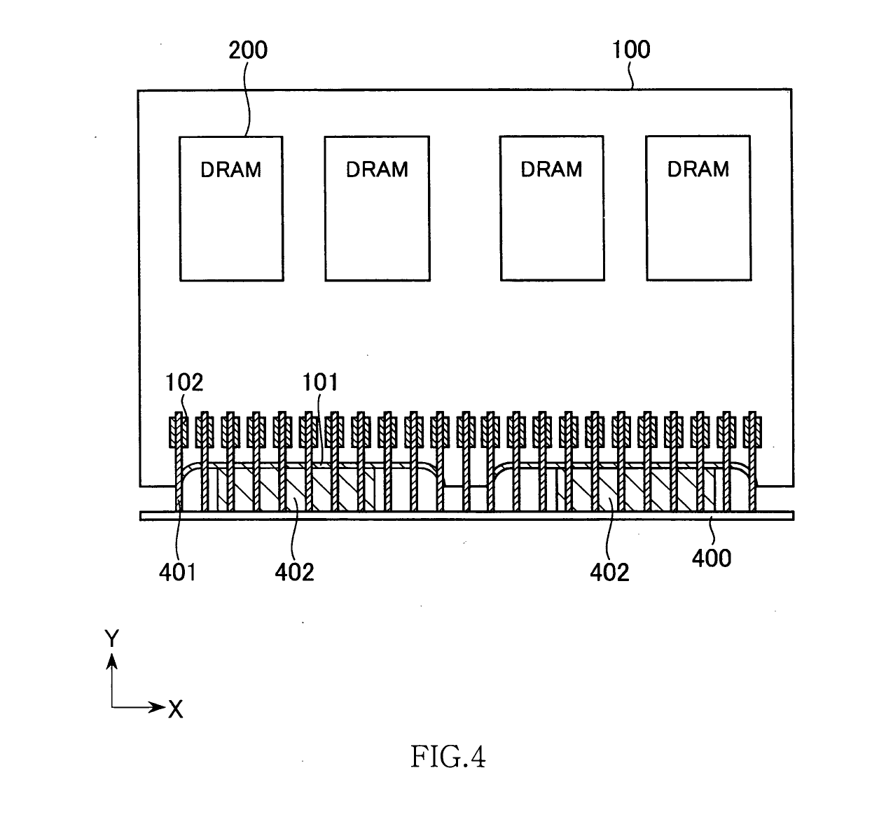

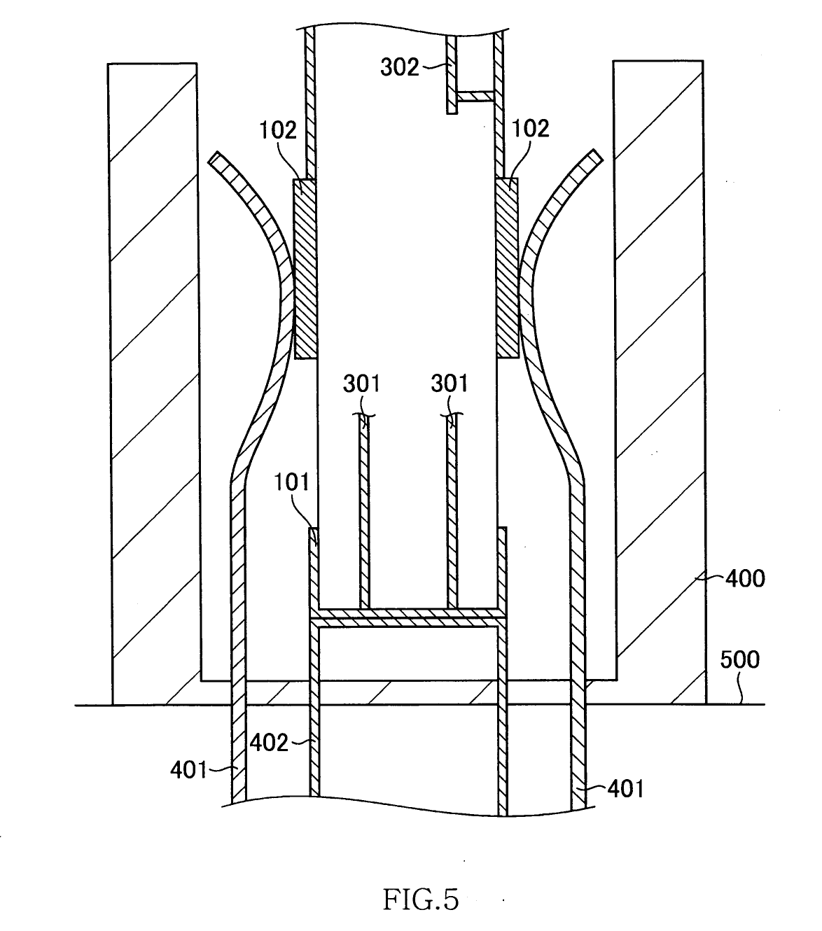

FIG. 4 is a schematic plan view and FIG. 5 is a schematic partial cross-sectional view showing a state where the memory module according to the first embodiment is attached to a socket.

As shown in FIG. 4 and FIG. 5, when the memory module according to the first embodiment is attached to a socket 400, wires 401 of the socket 400 contact the board terminals 102 and wires 402 of the socket 400 contact the board terminals 101. The socket 400 is arranged in a motherboard 500 that forms a memory system. The wires 401 are connected to a memory controller (not shown) mounted on the motherboard 500 and the wires 402 are connected to a power supply apparatus (not shown) that is mounted on the motherboard 500. As a result, signal transmission and reception is performed between the DRAMs 200 and the memory controller and power is supplied to the DRAMs 200 from the power supply apparatus.

Thus, according to the first embodiment, because the board terminals are provided not only on the main surface and the back surface but also on the side surface of the module board 100, the total number of board terminals that are required to be provided on the main surface and the back surface can be reduced. Further, because the board terminals 101 provided on the side surface are wider than the board terminals 102, and the wide board terminals 101 are used as the power terminals, there is no need to provide many power terminals that are required in the ordinary memory modules. For example, in a case of an ordinary 240-pin memory module, a VDD terminal having about 20 pins and a GND terminal having about 60 pins are provided. On the other hand, in the first embodiment, because all or some of the power terminals can be shifted from the main or back surface to the side surface, space becomes available in the area where terminals are provided on the main or back surface of the board so that more terminals can be provided on the main or back surface without reducing the size of the terminals. It is preferable that the surface area of the board terminal 101 that is used as the GND terminal is about three times the surface area of the board terminal 101 that is used as the VDD terminal.

A manufacturing method of the memory module according to the first embodiment is explained next.

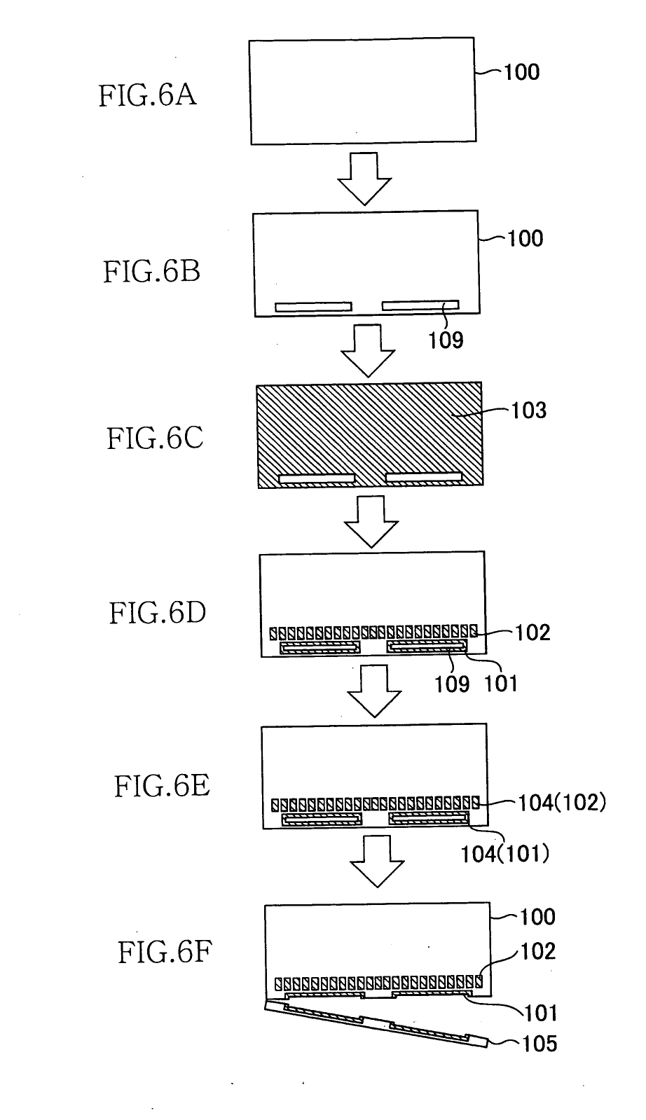

FIGS. 6A to 6F are process diagrams for explaining the manufacturing method of the memory module according to the first embodiment.

As shown in FIG. 6A, the module board 100 having a multilayered wiring structure is prepared first. As explained in connection with FIG. 3, the power wirings 301 and the signal wirings 302 are provided within the module board 100 and the through hole electrode 303 is used to connect the power wiring 301 to the signal wiring 302 of different layers.

Next, as shown in FIG. 6B, holes 109 that communicate from the main surface to the back surface are made in the module board 100 using a router and the like at places of the side surface where the board terminals 101 are to be formed. In this state, as shown in FIG. 6C, a metal film 103 is formed on the entire surface of the module board 100 including the internal walls of the holes 109. As a concrete method, electroless copper plating or electrolyte copper plating can be used to form the metal film 103. As a result, all the portions of the power wirings 301 and the signal wirings 302 that are exposed on the surface are connected to the metal film 103.

Next, the places where the board terminals 101 and 102 are to be formed are masked and the metal film 103 is subjected to patterning. As a result, as shown in FIG. 6D, the board terminals 101 and 102 are formed. At this time, to prevent the metal film 103 formed on the internal walls of the holes 109 from being removed, the patterning is performed in such a manner that the metal film 103 remains around the holes 109.

As shown in FIG. 6E, gold metal plating 104 is formed on the board terminals 101 and 102 and, as shown in FIG. 6F, a redundant portion 105 of the module board 100 is cut in a traversed manner at the holes 109 with a router and the like. With this process, the module board 100 is completed. Thereafter, when the DRAMs 200 are mounted on the main surface and the back surface, the memory module according to the first embodiment is completed.

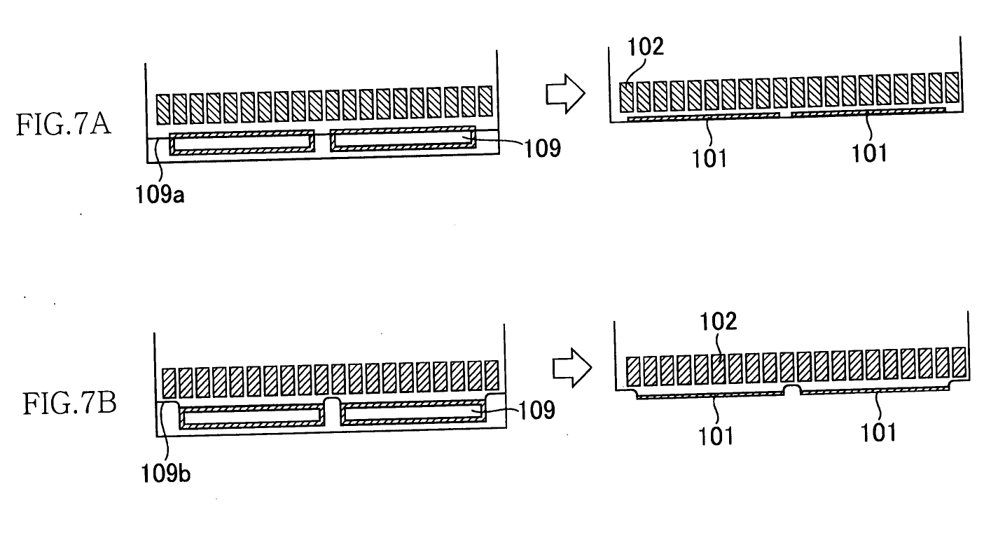

When the module board 100 is cut in a traversed manner at the holes 109, as shown in FIG. 1, it leads to a configuration in which the board terminals 101 are provided inside the cut out portion; however, this feature is not essential in the present invention. For example, as shown in FIG. 7A, a substantially step-less structure can be obtained by cutting the module board 100 along a line 109a that runs along the internal walls of the holes 109. Besides, as shown in FIG. 7B, a structure in which the board terminals 101 are formed on a salient can be obtained by cutting the module board 100 along a line 109b that detours from above the holes 109.

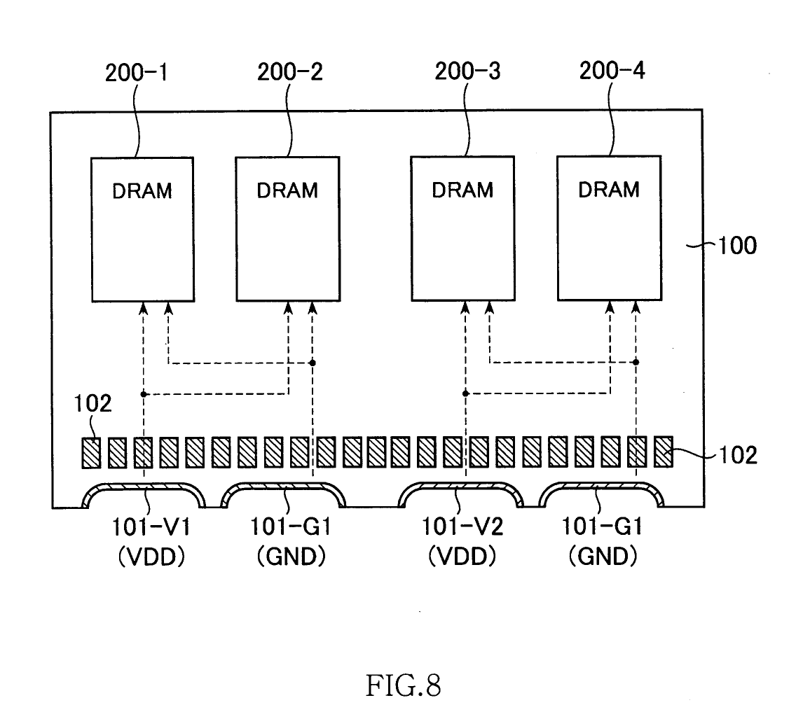

FIG. 8 is a schematic plan view of a configuration of a memory module according to the second embodiment of the present invention.

As shown in FIG. 8, in the second embodiment, four board terminals 101 are provided on the side surface. Among the four board terminals 101, a board terminal 101-V1 is a terminal for providing the power potential VDD to DRAMs 200-1 and 200-2 and a board terminal 101-G1 is a terminal for providing the ground potential GND to the DRAMs 200-1 and 200-2. On the other hand, a board terminal 101-V2 is a terminal for providing the power potential VDD to DRAMs 200-3 and 200-4 and a board terminal 101-G2 is a terminal for providing the ground potential GND to the DRAMs 200-3 and 200-4.

In this manner, in the second embodiment, a plurality of the DRAMs 200 are divided into groups and the power terminals are allocated per group. With this configuration, it is possible to make the power supply efficiency uniform for each of the DRAMs 200. It is needless to say that the power terminals can be allocated to individual DRAMs 200. When such a configuration is employed, it is possible to make the power supply efficiency almost perfectly uniform for each of the DRAMs 200.

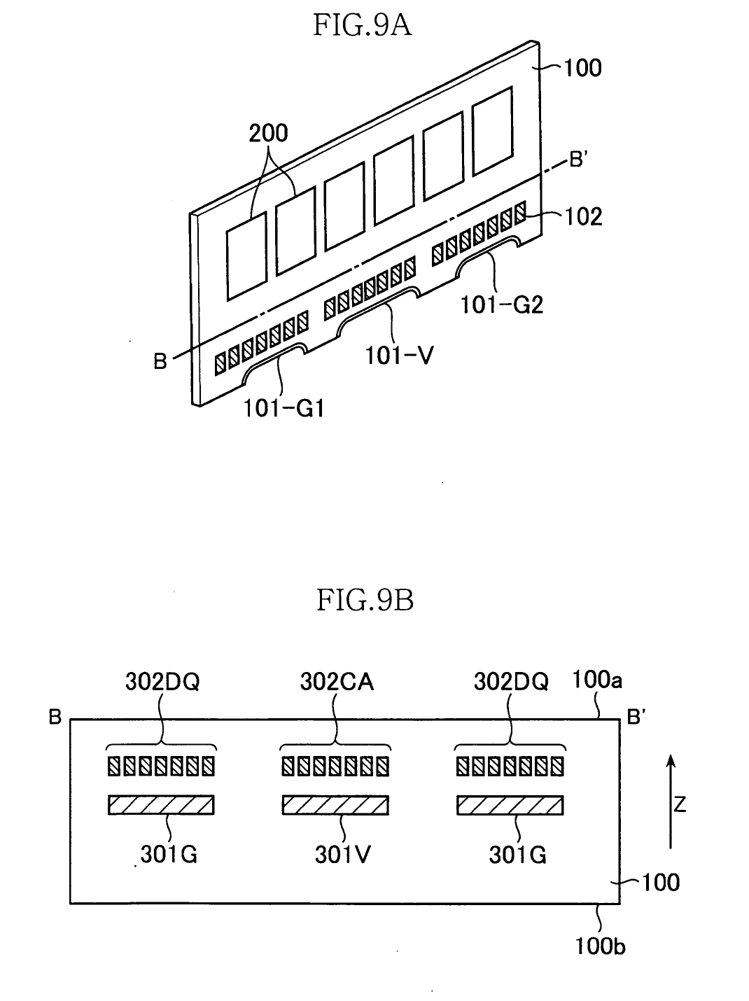

FIGS. 9A and 9B show a configuration of a memory module according to a third embodiment of the present invention, where FIG. 9A is a schematic perspective view of the memory module and FIG. 9B is a cross-sectional view of the memory module taken along a line B-B′ shown in FIG. 9A.

As shown in FIGS. 9A and 9B, in the third embodiment, three board terminals 101 are provided on the side surface. Among the three board terminals 101, board terminals 101-G1 and 101-G2 arranged on either sides are the terminals to which the ground potential GND is supplied and a board terminal 101-V arranged in between is a terminal to which the power potential VDD is supplied. Within the module board 100, as shown in FIG. 9B, a wide ground wiring 301G and a plurality of data wirings 302DQ are provided along each other so as to overlap in a laminating direction (the Z direction) of the module board 100 and, similarly, a wide VDD wiring 301V and a plurality of command address wirings 302CA are provided along each other so as to overlap in the laminating direction (the Z direction) of the module board 100.

With this configuration, the wide ground wiring 301G functions as a reference plate for the data wirings 302DQ and the wide VDD wiring 301V functions as a reference plate for the command address wirings 302CA. This configuration is similar to the wiring configuration on the motherboard. That is, even on the motherboard, a wide VSS wiring is provided as a reference plate for data wirings DQ and a wide VDD wiring is provided as a reference plate for command address wirings CA. With this configuration, the impedance of the signal wirings on the motherboard and the impedance of the signal wirings on the module board 100 can be made equal and the signal quality can be improved.

The wide ground wirings 301G and the wide VDD wiring 301V can be drawn simply from the board terminals 101 provided on the side surface so that the signal wirings and the power wirings do not need to be drawn wastefully inside the module board 100. As a result, lowering of the electric resistance of the signal wiring and the power wiring as well as simplification of the wiring layout on the module board 100 can be achieved.

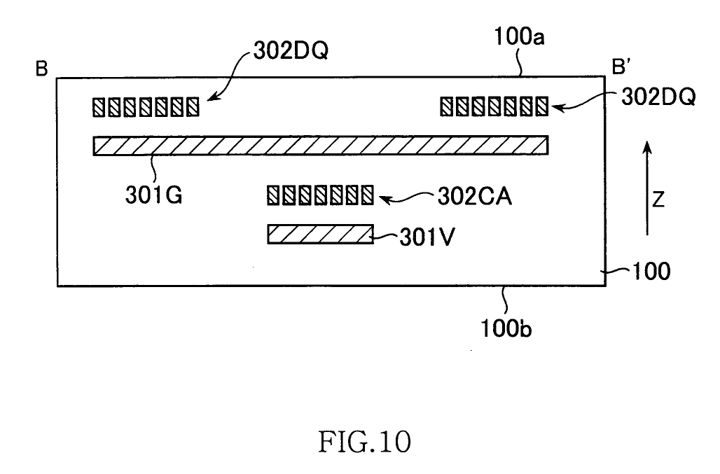

FIG. 10 is a modification example of the third embodiment. In the example shown in FIG. 9B, the wide ground wirings 301G and the wide VDD wirings 301V are formed in the same wiring layer; however, in the example shown in FIG. 10, these wirings are formed in different wiring layers. Similar effects can be achieved even with this layout.

It is apparent that the present invention is not limited to the above embodiments, but may be modified and changed without departing from the scope and spirit of the invention.

For example, in the above embodiments, there have been explained examples in which the present invention is applied to a memory module; however, the target of the present invention is not limited to memory modules, and the invention can be also applied to various types of modules having a semiconductor chip mounted thereon or even semiconductor devices other than these modules. In addition, the present invention can be also applied to a circuit board on which a semiconductor chip has not been mounted yet.

In addition, while not specifically claimed in the claim section, the applicant reserves the right to include in the claim section of the application at any appropriate time the following apparatus and method:

A1. A memory module connectable to a socket, comprising:

a circuit board including a main surface, a back surface parallel to the main surface, a side surface positioned between edges of the main surface and the back surface, and first and second board terminals covering a portion of the main surface and a portion of the side surface, respectively; and

a semiconductor memory mounted on the main surface of the circuit board and having at least a signal terminal and a power terminal, wherein

the first board terminal of the circuit board is electrically connected to the signal terminal of the semiconductor memory via a signal wiring provided on the circuit board, and

the second board terminal of the circuit board is electrically connected to the power terminal of the semiconductor memory via a power wiring provided on the circuit board.

B1. A manufacturing method of a circuit board comprising:

forming a hole that penetrates from a main surface to a back surface of a board;

forming a metal film on a surface of the board including an internal wall of the hole;

forming a first board terminal on the main surface and forming a second board terminal on the internal wall of the hole by patterning the metal film; and

cutting the board along the hole.

What is claimed is:

1. A circuit board comprising:
a main surface;
a back surface parallel to the main surface;
a side surface positioned between edges of the main surface and the back surface; and
first and second board terminals covering a portion of the main surface and a portion of the side surface, respectively.

2. The circuit board as claimed in claim 1, wherein the second board terminal includes:
a first part formed on the side surface over a total width between the edges of the main surface and the back surface;
a second part formed on the main surface and contacted to the first part via the edge of the main surface; and
a third part formed on the back surface and contacted to the first part via the edge of the back surface.

3. The circuit board as claimed in claim 1, wherein the second board terminals are provided in plural, and at least two of the second board terminals are supplied with mutually different power potentials.

4. The circuit board as claimed in claim 1, wherein the second board terminal is larger than the first board terminal.

5. The circuit board as claimed in claim 1, further comprising a plurality of power wirings, wherein
the power wirings are commonly connected to the second board terminal.

6. The circuit board as claimed in claim 1, further comprising a signal wiring connected to the first board terminal and a power wiring connected to the second board terminal, wherein
the signal wiring and the power wiring are provided along each other so as to overlap in a laminating direction of the circuit board.

7. The circuit board as claimed in claim 6, wherein a plurality of the signal wirings are provided along the power wiring.

8. The circuit board as claimed in claim 1, further comprising a third board terminal that covers a portion of the back surface.

9. A semiconductor device comprising:
a circuit board including a main surface, a back surface parallel to the main surface, a side surface positioned between edges of the main surface and the back surface, and first and second board terminals covering a portion of the main surface and a portion of the side surface, respectively; and
a semiconductor chip mounted on the main surface of the circuit board and having a plurality of chip terminals, wherein
the first and second board terminals of the circuit board are electrically connected to corresponding ones of the chip terminals of the semiconductor chip via an internal wiring provided inside the circuit board.

10. The semiconductor device as claimed in claim 9, wherein the second board terminal includes:
a first part formed on the side surface over a total width between the edges of the main surface and the back surface;
a second part formed on the main surface and contacted to the first part via the edge of the main surface; and
a third part formed on the back surface and contacted to the first part via the edge of the back surface.

11. The semiconductor device as claimed in claim 9, wherein the second board terminals are provided in plural, and at least two of the second board terminals are supplied with mutually different power potentials.

12. The semiconductor device as claimed in claim 9, wherein the second board terminal is larger than the first board terminal.

13. The semiconductor device as claimed in claim 9, wherein
the circuit board further includes a plurality of power wirings,
the power wirings are commonly connected to the second board terminal.

14. A memory system comprising a motherboard having a socket and a memory module connectable to the socket, wherein
the memory module includes:
a circuit board including a main surface, a back surface parallel to the main surface, a side surface positioned between edges of the main surface and the back surface, and first and second board terminals covering a portion of the main surface and a portion of the side surface, respectively; and
a semiconductor memory mounted on the main surface of the circuit board and having at least a signal terminal and a power terminal, wherein
the first board terminal of the circuit board is electrically connected to the signal terminal of the semiconductor memory via a signal wiring provided on the circuit board, and
the second board terminal of the circuit board is electrically connected to the power terminal of the semiconductor memory via a power wiring provided on the circuit board.

15. The memory system as claimed in claim 14, wherein the second board terminal includes:
a first part formed on the side surface over a total width between the edges of the main surface and the back surface;
a second part formed on the main surface and contacted to the first part via the edge of the main surface; and
a third part formed on the back surface and contacted to the first part via the edge of the back surface.

16. The memory system as claimed in claim 14, wherein the second board terminals are provided in plural, and at least two of the second board terminals are supplied with mutually different power potentials.

17. The memory system as claimed in claim 14, wherein the second board terminal is larger than the first board terminal.

18. The memory system as claimed in claim 14, wherein the power wiring is one of a plurality of power wirings that are commonly connected to the second board terminal.
